(19) United States
(12) Patent Application Publication
(10) Pub. No.: US 2007/0056844 A1
(43) Pub. Date: Mar. 15, 2007

(54) Coating machine and method for operating a coating machine

(76) Inventor: Oliver Heimel, Wabern (DE)

Correspondence Address: Kenneth J. Johnson, Esq.;Marsh Fischmann & Breyfogle LLP, Suite 411, 3151 South Vaughn Way, Aurora, CO, 80014, US

(21) Appl. No.: 11/293,052

(22) Filed: Dec. 2, 2005

(30) Foreign Application Priority Data
Sep. 15, 2005 (EP) 05020153.2

(51) Int. Cl. C23C 14/32; C23C 14/00

(52) U.S. Cl. 204/192.1; 204/298.02

(57) ABSTRACT

A coating machine for coating a substrate by means of sputtering, comprises a process chamber and, in the process chamber, targets 3, 3′ from which target material is sputterable in the direction of the substrate for coating the substrate. The coating machine features means of aligning the sputter direction S in a direction pointing away from direction S for pre-sputtering the target, and for aligning the sputter direction S in a direction pointing towards the substrate for coating the substrate by sputtering material from the targets 3, 3′. The change in alignment may, for example, be effected by rotating the cathodes 2, 2′ through an angle of 90° or 180° about a longitudinal axis of a flat cathode 2. A corresponding method features the following steps: Insertion of a target 3, 3′ into a coating chamber; evacuation of the coating chamber; alignment of the sputter direction S in a direction pointing away from the substrate plane 4; pre-sputtering of the target 3, 3′; alignment of the sputter direction S in a direction pointing towards the substrate plane 4; and coating of substrates by sputtering material from the targets 3, 3′.

This application concerns a coating machine for coating a substrate by means of sputtering comprising a process chamber and, positioned in the process chamber, a target from which target material can be sputtered in the direction of the substrate to coat the substrate, as well as a method for operating a coating machine.

In conventional coating machines, newly inserted targets have to be pre-sputtered or conditioned for a certain period of time in a vacuum prior to the start of the process. This is necessary because the sputtering target has to be conditioned prior to the start of the actual intended coating process in order that troublefree operation of the coating process may be safeguarded. Especially, the target has to be brought up to operating temperature prior to the start of the process by gradually increasing the sputtering power, as ceramic targets, in particular, can be destroyed by thermal stress when high sputtering power is abruptly introduced. Moreover, after the coating chamber has been flooded, the target is coated with interference materials, such as water molecules or dust, which stems from cleaning work. Even if the target surface is cleaned of residues, e.g. cutting oil, finger-prints etc., after it has been made, these contaminants may have penetrated into deeper molecular levels of the target material and may not be amenable to removal by the cleaning processes. For this reason, pre-sputtering serves inter alia to also liberate the target surface from these contaminants before the actual coating process commences.

During the pre-sputtering phase, a large number of substrates, such as a number ranging from roughly 80 to 100 substrates, is needed. This demand for substrates, which are needed for pre-sputtering the target each time the target has been changed, generates high costs. Furthermore, the substrates have to be disposed of as they are unfit for further use.

To cut these costs, it is possible, for example in coating machines with vertical alignment of the substrates, to use so-called dummy carriers for pre-sputtering instead of more expensive substrates on carriers. The use of dummies has two disadvantages, however. For one thing, when the pre-sputtering phase is completed, they also have to be disposed of or cleaned and stored free of dust and, for another, the subsequently used process carriers, which are transported past heating devices inside the machine during operation, are not brought up to operating temperature. That is to say, the pre-sputtering phase is not used to create the desired process conditions. Furthermore, the dummy carriers have to be provided in addition to the process carriers.

Another possibility consists in swiveling a so-called metal shutter into the gap between the target and the substrate, the purpose of said shutter being to absorb the particles sputtered in the pre-sputtering phase and to protect the substrate from undesired coating. Disadvantageous in this regard, aside from the elaborate mechanics for swiveling the shutter, is the fact that this shutter has to swivel close to the substrate, with the result that any particles of the coating which are expelled during the production process can get onto the substrate. Every further device for covering the surfaces coated in the pre-sputtering mode would render this solution more expensive.

Starting therefrom, the object of the present invention consists in providing a coating machine and a method for operating a coating machine by which the material outlay, especially the outlay on substrates, is reduced when the machine is being run in.

This object is achieved in this invention with a coating machine in accordance with claim 1 and a method in accordance with claim 22.

The coating machine of the invention for coating a substrate by means of sputtering comprises a process chamber and, positioned in the process chamber, a target from which target material can be sputtered in the direction of the substrate to coat the substrate, said coating machine having means of aligning the sputter direction in a first direction for operating the coating machine in a first operating mode and for aligning the sputter direction in a second direction for operating the coating machine in a second operating mode. The means are formed for optional varying of the sputter directions. Thus, for example, in every operating mode it can be determined whether the sputter direction should point towards the substrate or whether sputtering should occur in a different direction from that.

By sputter direction is meant the direction in which the sputtered material essentially moves. It is clear to a person skilled in the art that scattering of the movement directions of the particles in respect of a principal sputter direction occurs. One principal movement direction is determinable, however, that may be designated the sputter direction.

Alignment of the sputter direction or a change in the alignment when the operating mode is switched may be effected by operating personnel. The machine is designed such that the sputter direction may be varied without intervention in the coating chamber, that is without venting the chamber beforehand.

Especially, the first direction is a direction towards the substrate and the second direction is a direction away from the substrate. Thus, in various operating phases, there is scope for flexibly varying whether the substrates transported through the machine are coated or not during this phase.

By direction towards the substrate is meant essentially a direction perpendicular to the substrate surface or the transport plane in which the substrates are transported through the coating machine. The direction towards the substrate further means that the particles sputtered from the target in the sputter direction can reach the substrate surface without major further scattering.

The coating machine is variable such that, for pre-sputtering of the target, it is preferably in the second operating mode and, for coating the substrate by sputtering of material from the target, it is in the first operating mode. The possibility of varying the sputter direction between the minimum of two positions (the second for pre-sputtering in a direction away from the substrate, the first for regular, intended coating operation in a direction towards the substrate), without venting the machine for a change of alignment, is what determines the present invention.

In the present invention, the cathodes are formed such that the sputter direction is essentially aligned perpendicular to the surface of the target. The sputter direction in regular coating operation is thus essentially aligned perpendicularly to the target surface and perpendicularly to the substrate surface. Thus, the target surface, from which sputtering is preferably effected, is essentially parallel to the substrate surface.

During pre-sputtering, however, the sputter direction should be aligned in a direction pointing away from the substrate. This means that particles sputtered in the sputter direction should not reach the substrate surface. This is intended to prevent unnecessary consumption of substrates during the pre-sputtering phase. Since, however, the conditions within the coating machine are otherwise identical with the conditions during the intended coating process, empty substrate carriers may be transported through the machine to be heated up. This means that the pre-sputtering period may be used to create the process conditions necessary for operation. The carriers may be used effectively already at the start of the intended coating operation.

By “pre-sputtering” is meant in this connection the running in of the coating machine or the preliminary operation of a machine prior to the actual intended coating process.

The use of the coating machine as intended reduces the material requirements for substrates or dummy carriers, which subsequently have to be disposed of or cleaned and stored. This leads to cost advantages during operation of the machine.

The means for aligning the sputter direction are especially shaped such that the sputter direction may be varied by rotating the sputter direction through an angle, especially an angle between 90° and 180°. Consequently, the sputter direction can be rotated away from the substrate plane.

Preferably, the coating machine has a collecting device for collecting material sputtered from the target in the first direction. This collecting device may, for example, be a metal collector. In terms of shape and alignment, the collecting device is formed or positioned such that, during pre-sputtering, the fewest possible sputtered particles impinge on the transport plane for the substrates, contaminate walls or other components positioned inside the coating chamber.

The collecting device may have a surface that is positioned essentially perpendicularly to the second direction. Equally conceivable, however, are V-shaped arrangements of metal collectors positioned such that the opening area described by their edge is essentially positioned perpendicularly to the second direction, such that the sputtered particles pass through this opening. The collecting device should at any rate be formed and positioned such that the particles sputtered during the pre-sputtering phase impinge on the collecting area.

The coating machine has, especially, a flat cathode that carries the target. Flat cathodes have essentially a flat target surface, which in regular coating operation is essentially parallel to the transport plane of the substrates.

The means for aligning the sputter direction have especially a rotation mechanism for rotating the flat cathode. With the aid of the present invention, the sputter direction during the pre-sputtering phase can be rotated relative to the sputter direction during intended coating operation. Naturally, the rotation mechanism can be actuated externally, i.e. without venting of the machine, such that the sputter direction, depending on whether pre-sputtering or coating as intended is occurring, can be rotated between at least two directions.

The rotation mechanism may be formed such that the flat cathode is rotatable about a longitudinal axis of the cathode.

The cathode may be tilted or swiveled through an angle for pre-sputtering of the target relative to the substrate surface. This means that the target surface is rotated away from the substrate plane, preferably laterally, obliquely or in the opposite direction towards the rear. As a result, sputtered particles are prevented during pre-sputtering from impinging on the transport plane for the substrates and thus on the substrate carriers. Tilting of the cathodes also means that the axis of rotation need not necessarily lie centrally longitudinally to the cathode. The axis of rotation may be displaced both parallel and also slightly obliquely to the longitudinal axis of the cathode provided that the function of directing the sputter direction away from the target during the pre-sputtering phase is fulfilled.

The rotation mechanism may feature a motor drive.

In a further embodiment, the coating machine features a rotatable cathode which carries the target, with the target positioned such that it is rotatable relative to a carrier structure of the cathode. A rotatable cathode generally comprises a cylindrical carrier onto which is fitted the target material. In operation, the target is rotated in order that uniform removal of the material may be ensured. Further, provision is made for a magnet system, which essentially determines the sputter direction. The coating machine may feature a magnet system that, by means of a rotation mechanism, is positioned such that it can rotate relative to the carrier structure of the cathode. In this connection, the magnet arrangement may be rotated relative to the cathode between the pre-sputtering and the operating position.

The magnet system may be positioned on a magnet carrier. This means that the carrier, together with the magnet arrangement, is rotatable relative to the cathode.

The cathode, especially with its carrier structure and the magnet system, is positioned in the coating chamber such that it can be rotated by means of a rotation mechanism.

The rotation mechanism may feature a motor drive.

The cathode may also feature means for positioning a first magnet system for aligning the sputter direction in the first direction and means for positioning a second magnet system for aligning the sputter direction in the second direction. A rotatable magnetron is therefore fitted out with a second, additional magnetic field. Whereas the first magnetic field is positioned such that, under the action of this magnetic field, the target material is sputtered in the direction of the substrate for coating of the substrate, the second magnetic field is positioned such that, under the action of this magnetic field, the target material is sputtered in a direction away from the substrate. The arrangement of the magnets is such that an area, i.e. an angular section or sector, may be selected along which the target material is preferably sputtered.

The first magnet system is especially activated during the first operating mode, and the second magnet system during the second operating mode, with that magnet system being deactivated which is not required at that time.

If, instead of a magnet system which is fitted out with permanent magnets, use is made of a magnet system that is generated by means of coils, the magnetic field required in each case can be simply activated or deactivated. However, even magnet systems with permanent magnets can be activated or deactivated by moving a sufficiently thick, soft-magnetic metal shield about 5 mm thick in front of the magnet system not required, said metal shield, by virtue of its much greater magnetic permeability, almost completely absorbing and thus quasi short-circuiting the magnetic field emanating from the permanent magnet. Another possibility consists in arranging the magnet systems inside the tubular target such that they swivel, with deactivation effected by rotating the magnet poles towards the rotation axis of the tubular target. As a result, the field of the respective “rearwards” rotated magnet system on the target surface becomes so weak that a magnetron sputtering process cannot form.

The first magnet system and/or the second magnet system comprise therefore especially electromagnets that may be activated and deactivated by being switched on and off.

The first magnet system and/or the second magnet system may comprise permanent magnets, said magnet systems each being capable of activation and deactivation by positioning of a shielding element, especially a soft-magnetic metal shield, between the respective magnet system and the target surface.

The first magnet system and/or the second magnet system may comprise permanent magnets, and the magnet systems inside the target may be positioned such that the magnet systems are each capable of being activated and deactivated by swiveling the magnet poles of the respective magnet system relative to the target surface.

The object is also achieved by a method for operating a coating machine, especially a coating machine according to any of the previous claims, with the following steps:
a) Insertion of a target into a coating chamber;
b) Evacuation of the coating chamber;
c) Alignment of the sputter direction in a first direction pointing away from the substrate plane;
d) Pre-sputtering of the target;
e) Alignment of the sputter direction in a second direction towards the substrate plane; and
f) Coating of substrates by sputtering material from the target, with step c) capable of being performed before or after step b).

An angle between 90° and 180° especially may lie between the first direction and the second direction. The sputter direction during pre-sputtering is thus rotated, relative to the direction of the substrate, i.e. the direction in which sputtering is performed in regular coating operation, through an angle of at least 90°. During pre-sputtering, therefore, sputtering occurs not in the direction of the substrate but rather—as regards the substrate—laterally, obliquely to the rear, or to the rear in the direction opposite the substrate. As a result, undesired impinging is prevented of coating material on the substrates or substrate carriers that are moved through the coating chambers during sputtering.

In step a), aside from the target, a collecting device for collecting material sputtered in the first direction may be inserted into the coating chamber.

The collecting device may be positioned and formed such that the opening or impingement area described by its edge is positioned essentially perpendicularly to the second direction.

The sputter direction in step e) may be aligned by rotating a flat cathode.

The sputter direction may be tilted preferably through an angle of at least 90°.

The sputter direction in step e) may be aligned by rotating a magnet system of a rotatable cathode or by rotating the entire cathode.

The alignment of the sputter direction in steps c) and e) may also proceed by inserting or activating two magnet arrangements, which may be positioned radially offset in a rotatable cathode.

Further objects and advantages of the invention result from the following description of specific embodiments. In these,

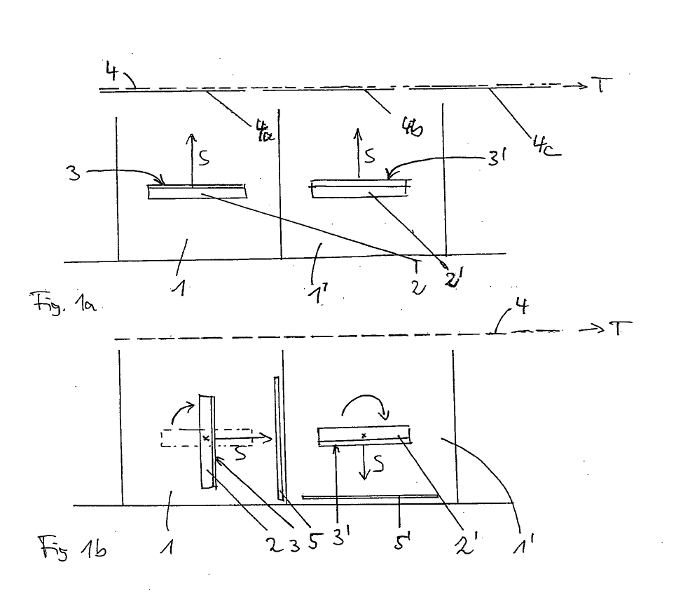

FIG. 1a is a section from a coating machine in cross-section;

FIG. 1b is a section from a coating machine of the invention in cross-section;

FIG. 2 is a plan view of a cathode structure with rotatable cathode;

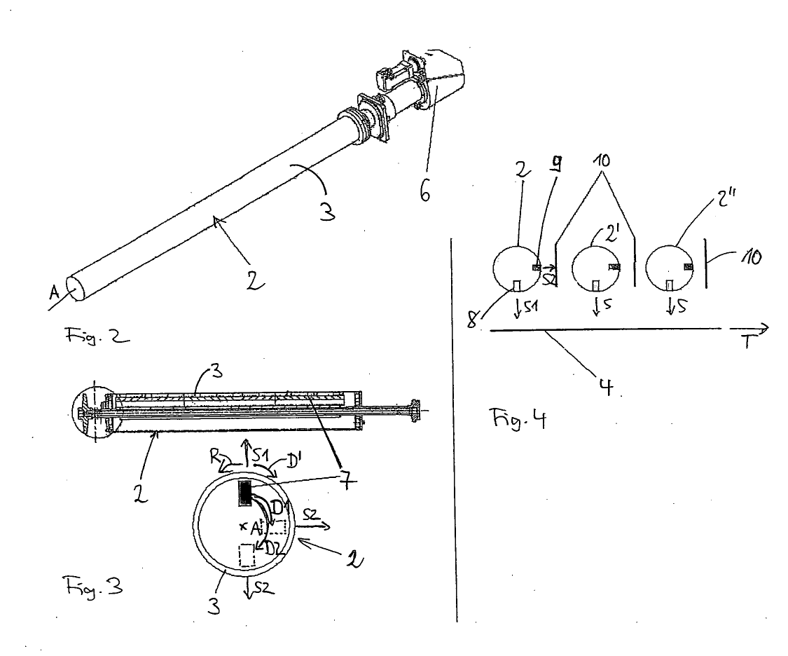

FIG. 3 is a sectional view of a rotatable cathode of the invention; and

FIG. 4 is a section from a coating machine of the invention in a further embodiment.

A sectional view of a sub-area of a coating machine is shown in FIG. 1a. The section comprises two compartments 1, 1′, in each of which is positioned a flat cathode 2, 2′. From target surface 3, 3′, coating material is sputtered to coat substrates 4a, 4b and 4c, which are transported past the target in a transport direction T. Plane 4, in which substrates 4a, 4b, 4c are essentially positioned during the coating process, is referred to below as the transport or substrate plane 4.

The particles sputtered from targets 3, 3′ have a movement direction facing the surfaces for coating of substrates 4a, 4b, 4c, said movement direction being designated the sputter direction S. In the case of flat cathodes 2, 2′, the sputter direction S1 is aligned essentially perpendicular to the target surface 3, 3′. Since, generally, target surface 3, 3′ is essentially aligned parallel to the transport direction T of substrates 4a, 4b, 4c, the transport direction T and sputter direction S1 are essentially also aligned perpendicular to each other. FIG. 1a shows the position of the cathodes 2, 2′ in regular, intended coating operation.

The sputtering rate of the target 3, 3′ can be increased by supplying a magnetic field of the prior art to the cathodes 2, 2′. The magnet arrangement, which generates the magnetic field, generally lies behind the target material, expressed in terms of transport plane 4.

During a pre-sputtering phase of the targets 3, 3′, as is necessary for example after a change of target, alignment of the cathodes 2, 2′ as shown in FIG. 1a causes qualitatively inadequate coating of a series of substrates 4a, 4b, 4c, with the result that the substrates 4a, 4b, 4c transported past targets 3, 3′ during this preliminary phase have to be disposed of thereafter. The use of these substrates 4a, 4b, 4c leads to a relatively high cost outlay before the machine proceeds to regular coating operation.

FIG. 1b reveals a solution to this problem in accordance with the invention. The flat cathodes 2, 2′ and the compartments 1, 1′ are fitted with a device for rotating the cathodes 2, 2′ in an alignment differing from the regular alignment (see FIG. 1a). The rotation device is naturally formed such that it can be actuated from outside, that is without opening and venting of the machine, and during operation of the machine. This means that a switchover can be performed by operating personnel between the two operating modes “pre-sputtering” and “coating operation as intended”, including when the machine is in operation.

Through rotation of the flat cathodes 2, 2′, the sputter direction S, which, for regular operation in accordance with FIG. 1a, was directed towards substrates 4a, 4b, 4c, is rotated away (direction S2) from substrates 4a, 4b, 4c or from the transport plane 4 of substrates 2.

In FIG. 1b, a first target 3, which is positioned in the first coating compartment 1, is rotated through about 90° relative to its original alignment (shown in dashed lines). Thus, the sputter direction S also rotates in a direction parallel to the surface of the substrates 4a, 4b, 4c or parallel to transport plane T.

Parallel to the target surface 3 of the flat cathode 2 rotated through 90°, a metal panel 5 is positioned for collecting the material sputtered from the target 3 during the pre-sputtering phase.

In the second compartment 1′, the cathode 2′ is rotated during the pre-sputtering phase through 180° relative to its operating position (see FIG. 1a). Thus, the sputter direction S2 during the pre-sputtering phase is the opposite to sputter direction S1 during regular operation. A metal collector 5′ is accordingly positioned at the rear of the compartment 1′.

Naturally, for pre-sputtering, cathode 2, 2′ may be rotated in any direction away from the transport plane 4, for example obliquely towards the rear. Accordingly, the metal collectors 5, 5′ are also aligned in this direction.

In the example of FIG. 1b, the rotation axis of the respective cathode 2, 2′ corresponds to a central longitudinal axis of the cathode 2, 2′. The rotation axis may, however, also be offset, for example laterally offset. The cathode 2, 2′ may be rotated, tilted or swiveled by any mechanism. The rotation mechanism in this case features, for example, a motor drive. This may be integrated into the cathode structure or the coating compartment 1, 1′.

In FIG. 1b, two different cathode positions specifically for pre-sputtering of the targets 3, 3′ are shown. The particles expelled from the target 3 during pre-sputtering are collected by metal panels 5 or 5′. The metal panels 5 and 5′ may be swapped along with the target 3, 3′ during a target change.

As soon as a target 3, 3′ is operational, the cathodes 2,2′ are rotated into the operating position shown in FIG. 1a, with the sputter direction S rotated in the direction of the substrate plane 4 parallel to the target surface 3, 3′. In this position of the targets 3, 3′, the substrates 4a, 4b, 4c may be coated.

FIG. 2 shows a cathode structure with an essentially cylindrically formed rotatable cathode 2, which for example may be used in the field of glass coating, monitor production and the like. The target material 3, as may be seen from the sectional view in FIG. 3, is positioned on an essentially cylindrical support structure in the cathode structure shown. The rotatable cathode 2 is rotated in operation about its central axis A by a drive 6 for uniform exploitation and removal of material from the target.

As illustrated in FIG. 3 in a sectional view along a longitudinal axis or perpendicular to a longitudinal axis of the cathode 2, the cathode 2 features a magnet system 7 for increasing the sputter rate. In the case of rotatable cathodes, the arrangement of the magnet system 7 essentially determines the sputter direction S1, S2. In the current embodiment, the magnet system 7, as especially revealed from the radial sectional diagram, is positioned radially in a certain direction S1, which essentially corresponds to the sputter direction. Consequently, the magnetic field is also oriented in this direction. For coating operation in the intended manner, the magnet system 7 is positioned such that it is stationary in the coating chamber while the target 3 is rotated about the longitudinal axis of the cathode in the direction indicated by the arrow R. In this operating mode, the magnet system 7 is positioned such that the sputter direction S1 is oriented essentially perpendicularly to the surface of the substrates (not indicated) to be coated.

While in the case of conventional coating machines with rotatable cathodes, substrates that later have to be disposed of or dummies are sputtered during the pre-sputtering phase, in the arrangement of the invention, the magnet system 7 of the rotatable cathode may be rotated about an axial axis A to change the sputter direction S. Similar to what is shown in connection with the flat cathode 2 in FIG. 1, the magnetic field may, for example, be rotated through 90° to the side (arrow D1), through 180° to the rear (arrow D2), or turned in any desired direction, e.g. obliquely to the rear, away from the substrate surface or the transport plane. In choosing the angle of rotation, the machine configuration may be taken into account. As soon as the target is ready for operation, the magnet system 7 (and thus the sputter direction) is directed towards the substrates or to the substrate transport plane.

In FIG. 3., the rotation of the magnet arrangement 7 into a position which the magnet system 7 is to assume for pre-sputtering is illustrated by the arrows D1 and D2 and the positions of the magnet system 7 after rotation. With the magnet arrangement 7, the sputter direction is accordingly rotated from a direction S1 for coating operation into respectively one selected direction S2 for pre-sputtering.

However, provision may also be made for the fact that, for pre-sputtering, the entire cathode 2, along with the magnet system 7, as indicated in FIG. 3. by the arrow D′, is rotated. The angle of rotation may therefore be chosen according to the machine configuration.

The rotation mechanism for the magnet system 7 can have any form. For example, provision may be made for a motor drive with whose aid the magnet system 7 can be rotated about the longitudinal axis A of the cathode between the pre-sputtering phase and the start of the regular coating operation.

To an extent depending on space conditions, rotation of the magnet system 7 between the pre-sputtering position and the operating position may be realized through the execution of a further rotation. In this regard, the entire cathode 1 could be rotatable through a corresponding angle, or simply the magnet carrier, to which the magnet system 7 is attached, could be rotatable. Provision could also be made for a separate carrier for the magnet system 7, which said carrier can be rotated along with the magnet system 7 relative to cathode 1.

Also when rotatable cathodes 2 are used, metal panels or collector surfaces in the coating chamber are positioned in the sputter direction S2 intended for pre-sputtering. The metal panels are formed and positioned such that no sputtered material impinges on the substrates or the transport plane during pre-sputtering. The metal panels may be swapped along with the target 3 during a target change.

A further alternative embodiment of the invention is shown in FIG. 4. The figure shows a section from a coating machine with three rotatable cathodes 2, 2′, 2″ positioned one behind the other. Each of these cathodes 2, 2′, 2″ has a first magnet arrangement 8 that generates a magnetic field in the direction of the substrate plane 4, such that a first sputter direction S1 is directed essentially perpendicularly to the substrate surface 4 during regular, intended coating operation. In addition, each of the cathodes 2, 2′, 2″ features a further magnet arrangement 9, however, that generates a magnetic field such that the sputter direction is rotated in a direction S2 pointing away from the transport plane 4. This second magnetic field pointing away ensures that, during the pre-sputtering phase, the sputtered material is collected by the metal panels 10 positioned laterally beside the cathode 2. Especially in the case of a coating machine with vertically positioned cathodes 2, 2′, 2″, the second sputter direction S2 is rotated through 180° relative to the first. In this way is achieved the least possible impairment of production coating by any particles spalling away from the metal collector 10 during intended coating operation. The same also applies, however, to machines with horizontal alignment of the cathodes, for example in the case of glass-coating machines that are operated by the “sputter-up” method (sputter direction S1 upwards). In the case of machines with horizontal alignment of the cathodes in the “sputter-down” (sputter direction S1 downwards) direction, in contrast, a second sputter direction S2 is more favorable, which is rotated through approx. 90° relative to the sputter direction S1 chosen for coating operation, as shown in FIG. 4. In this arrangement, the metal collector 10 can be shaped such that the downwardly falling particles are collected. For example, a metal panel with an L-shaped cross-section may be used in whose essentially horizontal section the downwardly falling particles collect. It is clear that a 180° rotation of the two sputter directions S1 and S2 towards each other in the “sputter-down” process would be less favorable, as the metal collector in that case would be positioned above the cathode or the substrate transport plane 4 and the spalling particles would have to fall on the substrates passing by.

As already described, the sputter direction S2 for the pre-sputtering operation could also be aligned obliquely or through 180° towards the rear. The metal collectors 10 would accordingly be positioned such that the inside of the coating chamber is contaminated as little as possible.

During the pre-sputtering phase when the machine is operated, only the second magnet system 9 is activated in the cathode whereas the first magnet system 8 is inserted or activated in regular coating operation. It goes without saying that the activation of the first or the second magnet system 8, 9 may be performed without prior venting of the machine, so that a direct operational transition can take place between the two operating phases.

For all embodiments described, the invention is implementable both in the case of vertical, horizontal or oblique installation of the installation cathodes or the rotatable cathodes, depending on the type of coating machine. Accordingly, the collecting devices can also be positioned horizontally, obliquely or vertically.-{ }-

For collecting material that detaches unintentionally from the metal collectors, containers may be positioned beneath the metal collectors for collecting said material.

With the aid of the proposed solutions, the use of substrates that are coated during the pre-sputtering phase or the use of dummy carriers may be eschewed. Consequently, the operating costs can be lowered overall. Moreover, the need to dispose of the substrates or the dummies that have been coated during the pre-sputtering phase is obviated.

1-29. (canceled)

30. A coating machine for coating a substrate by means of sputtering, comprising:
a process chamber;
a target positioned in the process chamber, from which target material is sputterable in the direction of a substrate for coating the substrate; and
means for aligning the sputter direction in a first direction for operating the coating machine in a first operating mode and for aligning the sputter direction in a second direction for operating the coating machine in a second operating mode.

31. The coating machine of claim 30, wherein the first direction is a direction towards the substrate and the second direction is a direction away from the substrate.

32. The coating machine of claim 30, wherein the coating machine is adjustable in a first operating mode for coating the substrate by sputtering material from the target, and in a second operating mode for pre-sputtering the target.

33. The coating machine of claim 30, wherein the means for aligning the sputter direction enable the sputter direction to be varied by rotating the sputter direction through an angle.

34. The coating machine of claim 33, wherein said angle is between 90° and 180°.

35. The coating machine of claim 30, further comprising a collecting device for collecting material sputtered from the target in the second direction.

36. The coating machine of claim 35, wherein the collecting device is positioned and formed such that the opening or impingement surface defined by its edge is positioned essentially perpendicular to the second direction.

37. The coating machine of claim 30, further comprising a flat cathode that carries the target.

38. The coating machine of claim 37, wherein the means for aligning the sputter direction comprises a rotation mechanism for rotating the flat cathode.

39. The coating machine of claim 38, wherein the rotation mechanism is formed such that the flat cathode is rotatable about a longitudinal axis of the cathode.

40. The coating machine of claim 37, wherein the cathode may be rotated through an angle relative to the substrate surface for pre-sputtering of the target.

41. The coating machine of claim 40, wherein said angle is between 90° and 180°.

42. The coating machine of claim 38, wherein the rotation mechanism comprises a motor drive.

43. The coating machine claim 30, further comprising a rotatable cathode, which carries the target, with the target positioned such that it is rotatable relative to a carrier structure of the cathode.

44. The coating machine of claim 43, further comprising a magnet system that, by means of a rotation mechanism, is positioned such that it is rotatable relative to the carrier structure of the cathode.

45. The coating machine of claim 44, wherein said magnet system is positioned on a magnet carrier.

46. The coating machine of claim 44, wherein said cathode with its carrier structure and said magnet system is positioned in the coating chamber such that it is rotatable by means of a rotation mechanism.

47. The coating machine of claim 44, wherein the rotation mechanism comprises a motor drive.

48. The coating machine of claim 43, wherein the cathode comprises means for the positioning of a first magnet system for aligning the sputter direction in the first direction and means for the positioning of a second magnet system for aligning the sputter direction in the second direction.

49. The coating machine of claim 48, wherein the first magnet system is activated during the first operating mode and the second magnet system is activated during the second operating mode.

50. The coating machine of claim 49, wherein the first magnet system and/or the second magnet system comprises electromagnets that may be activated and deactivated by being switched on and off.

51. The coating machine of claim 49, wherein the first magnet system and/or the second magnet system comprises permanent magnets, said magnet systems each capable of being activated and deactivated by positioning of a shielding element between the respective magnet system and the target surface.

52. The coating machine of claim 51, wherein said shielding element comprises a soft-magnet metal shield.

53. The coating machine of claim 49, wherein the first magnet system and/or the second magnet system comprises permanent magnets, and the magnet systems inside the target are positioned such that the magnet systems are each capable of being activated and deactivated by swiveling the magnet poles of the respective magnet system relative to the target surface.

54. A method for operating a coating machine, comprising the steps of:
(a) inserting a target into a coating chamber;
(b) evacuating the coating chamber;
(c) aligning the sputter direction in a first direction away from the substrate plane;
(d) pre-sputtering the target,
(e) aligning the sputter direction in a second direction towards the substrate plane; and
(f) coating substrates by sputtering a material from the target, wherein step (c) is capable of being performed before or after step (b).

55. The method according to claim 54, wherein an angle between 90° and 180° lies between the first direction and the second direction.

56. The method of claim 54, further comprising the step of inserting a collecting device for collecting material sputtered in the first direction into the coating chamber.

57. The method of claim 56, wherein the collecting device is positioned such that the opening or impingement surface described by its edge is aligned essentially perpendicularly to the second direction.

58. The method of claim 54, wherein the sputter direction in step (e) is aligned by rotating a flat cathode.

59. The method of claim 58, wherein the sputter direction is rotated through an angle between 90° and 180°.

60. The method of claim 54, wherein the sputter direction in step (e) is aligned by rotating a magnet system of a rotatable cathode or by rotating the tubular cathode carrying the magnet system.

61. The method of claim 54, wherein the alignment of the sputter directions in steps (c) and (e) proceeds by activating and deactivating at least two magnet arrangements, which may be positioned radially offset in a rotatable cathode.
